(19) United States
(12) Patent Application Publication
(10) Pub. No.: US 2025/0138417 A1
(43) Pub. Date: May 1, 2025

(54) ADDITIVES FOR METALLIC PHOTORESIST

(71) Applicant: Taiwan Semiconductor Manufacturing Company Ltd, Hsinchu (TW)

(72) Inventors: Shi-Cheng Wang, Tainan (TW); An-Ren Zi, Hsinchu (TW); Ching-Yu Chang, Yuansun (TW)

(21) Appl. No.: 18/385,563

(22) Filed: Oct. 31, 2023

(51) Int. Cl. G03F 7/004

(52) U.S. Cl. CPC G03F 7/0044

(57) ABSTRACT

Methods and materials for improving the hardness of a metallic photoresist used in EUV photolithography are disclosed. Multiple different additive types are described for use with the metallic photoresist. The additives can be applied to the photoresist as part of existing solutions, or applied as an ingredient in a treatment solution during various steps for applying, patterning, and developing the metallic photoresist. The resulting photoresist layer has increased hardness and higher EUV light sensitivity, which permits a reduced radiation dosage.

### BACKGROUND

Integrated circuits are formed on a semiconductor wafer. Photolithographic patterning processes use ultraviolet light to transfer a mask pattern to a photoresist on a semiconductor wafer. Etching processes may then be used to transfer to the pattern to a layer below the photoresist. This process is repeated multiple times with different patterns to build different layers on the wafer substrate and make a useful device.

High-resolution lithography processes help to obtain smaller feature sizes. An example of one such process is extreme ultraviolet (EUV) lithography, which uses wavelengths of about 10 nanometers (nm) to about 100 nm.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a flow chart illustrating a method for preparing a patterned photoresist layer and etching a layer of a semiconducting device, in accordance with some embodiments.

FIG. 1B is a second flow chart illustrating other aspects of the method.

FIG. 2A is a cross-sectional view of a substrate prior to starting the method of FIG. 1A and FIG. 1B.

FIG. 2B is a cross-sectional view of a substrate with a first material layer located upon the substrate, again prior to starting the method of FIG. 1A and FIG. 1B.

FIG. 3 is a cross-sectional view of the substrate with two underlayers applied upon the first material layer.

FIG. 4 is a cross-sectional view of the substrate with a photoresist layer applied upon the two underlayers.

FIG. 5 is a cross-sectional view of the substrate after radiation exposure, with the photoresist layer now including soluble regions and insoluble regions.

FIG. 6 is a cross-sectional view of the substrate after development, with a patterned photoresist layer.

FIG. 7 is a cross-sectional view of the final structure with a patterned first material layer.

FIG. 8 is an illustration of an extreme ultraviolet (EUV) photolithography system for exposing the photoresist layer to EUV radiation, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The term “alkyl” is used herein to refer to a radical composed from a chain of carbon atoms which is fully saturated (i.e. contains only single bonds). The alkyl radical may be linear, branched, or cyclic.

The terms “aromatic” or “aryl” refer to a group that has a ring system containing a delocalized conjugated pi system with a number of pi-electrons that obeys Huckel's Rule. The ring system is composed of carbon atoms and hydrogen atoms. Examples of aromatic groups include phenyl (derived from benzene) and other polycyclic aromatic hydrogens such as naphthyl (derived from naphthalene) or phenanthryl (derived from phenanthrene). Generally, the aromatic group is planar and un-charged.

The term “heteroaryl” refers to a cyclic radical composed of carbon atoms, hydrogen atoms, and a heteroatom within a ring of the radical, the cyclic radical being aromatic. The heteroatom may be nitrogen, sulfur, or oxygen. Exemplary heteroaryl groups include thienyl, pyridinyl, furanyl, pyrryl, indolyl, and quinolinyl. The heteroaryl radical has the ability to form a single bond to one or two different non-hydrogen atoms, depending on the context. For example, the radicals —C₄H₃S and —C₄H₂S— could both be referred to as thienyl, and should both be considered heteroaryl radicals. As used herein, a heteroaryl group has from 5 to about 18 carbon atoms.

The term “alkenyl” as used herein refers to a radical composed from a chain of carbon atoms which contains at least one carbon-carbon double bond and is not aromatic. The alkenyl radical may be linear, branched, or cyclic.

The term “alkynyl” as used herein refers to a radical composed from a chain of carbon atoms which contains at least one carbon-carbon triple bond and is not aromatic. The alkynyl radical may be linear, branched, or cyclic.

The terms “vinyl” or “ethenyl” as used herein refer specifically to a functional group of the formula —(C═C)—, having a carbon-carbon double bond, with each carbon atom being bonded to two other atoms, and which is not aromatic. The vinyl group is generally present in a hydrocarbon group (linear, branched, or cyclic). A vinyl group is able to participate in cross-linking reactions, and so the carbon-carbon double bonds present in an aromatic group are not considered to be vinyl groups.

The terms “acetylene” or “ethynyl” as used herein refer specifically to a functional group of the formula —(C═C)—, having a carbon-carbon triple bond, with each carbon atom being bonded to one other atom, and which is not aromatic. The acetylene group is generally present in a hydrocarbon group (linear, branched, or cyclic).

The term “hydrocarbon” is used herein to refer to a radical composed from a chain of carbon atoms which can be fully saturated or unsaturated, and is not aromatic. The hydrocarbon radical may be linear, branched, or cyclic. The hydrogen atoms may be substituted with other radicals. Alkyl, alkenyl, and alkynyl groups are subsets of hydrocarbons.

The term “halogen” as used herein refers to fluorine, chlorine, bromine, and iodine.

The term “ether” refers to a radical in which an oxygen atom is covalently bonded to two different carbon atoms.

The term “substituted” refers to at least one carbon atom or hydrogen atom on the named radical being substituted with a heteroatom or another functional group. An example of a substituted alkyl group is a perhaloalkyl group, wherein the hydrogen atoms in an alkyl group are replaced with halogen atoms. Another example of a substituted alkyl group is tetrahydrofuran, where a methylene group is substituted with an oxygen atom. Aryl and heteroaryl groups may be substituted with alkyl, alkenyl, or alkynyl groups.

The present disclosure may refer to temperatures for certain process steps. It is noted that these generally refer to the temperature at which the heat source (e.g. furnace) is set, and do not necessarily refer to the temperature which must be attained by the material being exposed to the heat.

The term “ambient temperature” or “room temperature” refers to a temperature of 20° C. to 25° C.

The present disclosure relates to structures which are made up of different layers. When the terms “on” or “upon” are used with reference to two different layers (including the substrate), they indicate merely that one layer is on or upon the other layer. These terms do not require the two layers to directly contact each other, and permit other layers to be between the two layers. For example all layers of the structure can be considered to be “on” the substrate, even though they do not all directly contact the substrate. The term “directly” may be used to indicate two layers directly contact each other without any layers in between them. In addition, when referring to performing process steps to the substrate, this should be construed as performing such steps to whatever layers may be present on the substrate as well, depending on the context.

The present disclosure relates to various methods for improving the operation of a metallic photoresist. In this regard, chemically amplified photoresist may be considered as operating through a multi-step reaction mechanism. First, when exposed to EUV radiation, the photoresist absorbs photons from the radiation. Second, secondary electrons are emitted by the photoresist, and thermal electrons are also generated. Third, photo-acid generators (PAGs) react with these electrons to generate photoacids. Fourth, the photoacids diffuse through the photoresist matrix. Fifth and last, the photoacid catalyzes the degradation of acid-sensitive groups from the photoresist, also known as deprotection. The photoacid is not consumed in this reaction, and can thus catalyze multiple deprotection reactions. The deprotected photoresist differs from the original photoresist in solubility. This difference in the photoresist between exposed areas and non-exposed areas permits patterning of the photoresist, which is used to build different layers on the wafer substrate. A metallic photoresist includes metal atoms to increase photon absorption, i.e. the first step of the reaction mechanism. The patterned photoresist layer is then used as a mask for performing various processes, such as etching a lower layer or depositing a new layer.

The present disclosure relates to methods and materials for increasing the hardness of the resulting metallic photoresist layer and/or for reducing the radiation dosage needed to pattern the metallic photoresist. The metallic photoresist is exposed to an additive having a structure as described herein during the photoresist development process. The photoresist development process includes the steps of coating the substrate, a prebake or softbake, radiation exposure, an optional post-exposure bake, development, and an optional hardbake. The additive can be applied during or between any of these process steps. The additive is triggered by hydrogen bonding and/or chemical bonding from acid or base catalysis. The acid or base can be generated from native acid/base or photo-generated acid/base. An increased hardness provides higher etch selectivity, better critical dimension (CD) control, and increases the aspect ratio that can be achieved. Initially, the metallic photoresist is described. Next, the additive is described. Then, other components that may be present in photoresist solutions and methods for using the photoresist solutions will be described.

### Metallic Photoresist

The metallic photoresist of the present disclosure comprises a metal core and one or more ligands attached to or connected to the metal core. The ligand(s) may be attached via covalent, ionic, or metallic bonds or via van der Waals forces to the metal core.

The metal core of the metallic photoresist includes a metallic element. The metallic element may be present as a pure metal (i.e. atom), an ion, a compound (for example a metal oxide, metal nitride, metal oxynitride, metal silicide, metal carbide, etc.), or as an alloy of multiple metal atoms. Desirably, the metallic element has a high EUV photoabsorption. Examples of suitable metallic elements include silver (Ag), cadmium (Cd), indium (In), tin (Sn), antimony (Sb), tellurium (Te), cesium (Cs), gold (Au), mercury (Hg), titanium (Ti), lead (Pb), bismuth (Bi), polonium (Po), astatine (At), barium (Ba), lanthanum (La), cerium (Ce), hafnium (Hf), zirconium (Zr), chromium (Cr), tungsten (W), molybdenum (Mo), iron (Fe), ruthenium (Ru), osmium (Os), cobalt (Co), rhodium (Rh), iridium (Ir), nickel (Ni), palladium (Pd), platinum (Pt), copper (Cu), zinc (Zn), aluminum (Al), gallium (Ga), thallium (TI), and germanium (Ge). In more specific embodiments, the metal core of the metallic photoresist comprises Ag, Cd, In, Sn, Sb, Te, Cs, Au, Hg, Ti, Pb, Bi, Po, At, Ba, La, or Ce. The metallic elements in the metal core of the metallic photoresist may comprise from about 0.01 wt % to about 7 wt % of the photoresist solution. In some particular embodiments, only one metallic element is present in the metal core. In other embodiments, multiple metallic elements are present in the metal core.

The ligand(s) are attached to the metal core, and this attachment determines whether the photoresist is soluble or insoluble when exposed to developer. One function of the ligand(s) is to protect the metal core from condensation prior to radiation exposure. In particular embodiments, there are from 1 to about 18 ligands attached to the metal core. In some embodiments, the ligands are hydrolysable. When hydrolyzed, the metal core can undergo condensation reactions to form an organometallic polymer for the photoresist. In other embodiments, the ligands may be cleaved from the metal core during radiation exposure or heat treatment to permit the metal cores to crosslink with each other and form the metallic photoresist.

The individual ligands themselves can be synthesized using conventional methods known in the art. The metal core can also be synthesized using conventional methods known in the art. The ligand(s) can be attached to the metal core using conventional methods known in the art. The metallic photoresist is suited for EUV photolithography processes where a pitch of less than 40 nanometers (nm) is desired.

### Additives

During the photoresist development process, the metallic photoresist can be exposed to an additive to enhance the properties of the metallic photoresist, especially its hardness. In contrast to the metallic photoresist, the additive does not contain metal. 13 different types or structures of additives are described herein. It is noted that a given compound may fall within more than one type of additive, particularly when substituents are present. The additives are photosensitive. Upon exposure to radiation or heat, the additives may decompose and react with the photoresist, or they may crosslink, or they may polymerize. More than one additive type may be used in the photoresist development process, if desired.

In particular embodiments, the additive has a molecular weight of about 30 to about 2000 daltons (also known as atomic mass unit or amu), although other values and ranges are also within the scope of this disclosure. Generally speaking, as well, the additive usually contains a total of from 1 to 30 carbon atoms, or in some further embodiments a minimum of 6 carbon atoms, although other values and ranges are also within the scope of this disclosure.

The first type of additive (Type 1) contains at least one cyclic ether group. Examples of cyclic ether groups include epoxy (oxirane) groups (C₂O), oxetane groups (C₃O), tetrahydrofuran groups (C₄O), and tetrahydropyran groups (C₅O). In particular embodiments, such additives may have the structure of Formula (1-A) or Formula (1-B):

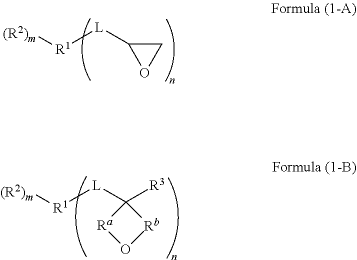

wherein R¹ is H, hydrocarbon, substituted hydrocarbon, aryl, or heteroaryl;
each R² is independently hydrocarbon or a substituent that contains a heteroatom;
m is an integer from 0 to 12;
each L is —O—, —S—, hydrocarbon, substituted hydrocarbon, or a combination thereof;
each R^{a} and R^{b} are independently alkylene having 0 to 3 carbon atoms but together have a minimum of 2 carbon atoms;
each R³ is independently H, hydrocarbon, substituted hydrocarbon, aryl, or heteroaryl; and
n is an integer from 1 to 20.

Formula (1-B) includes oxetane groups (C₃O), tetrahydrofuran groups (C₄O), and tetrahydropyran groups (C₅O), where the oxygen atom is in any location relative to the linker L. When R¹ is not H, the cyclic ether group(s) may be attached to any carbon atom or suitable heteroatom of R¹. In some particular embodiments of Formula (1-A) and Formula (1-B), R¹ is aryl or alkyl having 1 to 20 carbon atoms. In other particular embodiments, each L is —O—, —S—, alkyl, or a combination thereof. In additional particular embodiments of Formula (1-B), R³ is alkyl, fluoroalkyl, or aryl having 1 to 20 carbon atoms. Combinations of these embodiments are also contemplated.

Non-limiting examples of substituents for R² can include halogen, —OH, —SH, —NO₂, —SO₂R, —SO₃R, —CN, —COR, —CO₂R, or —CONR₂, where each R is independently hydrogen or alkyl.

Some non-limiting examples of Type 1 additives containing one or more cyclic ether groups are shown below as Formulas (1-1) through (1-4):

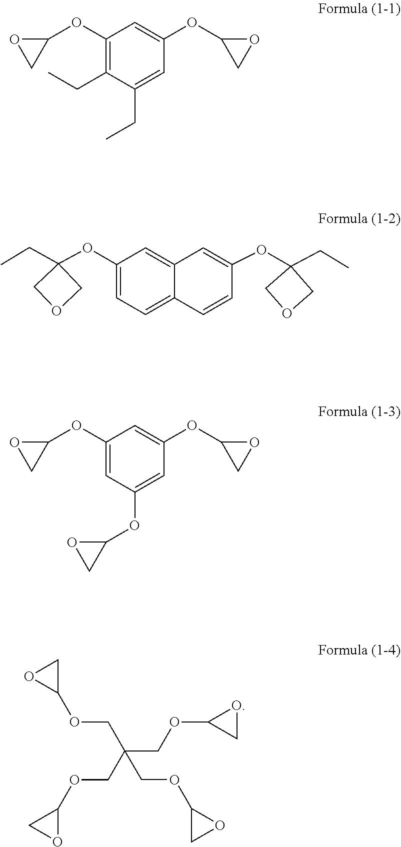 [SMILES: CCc1cc(OC2CO2)cc(OC2CO2)c1CC ; CCC1(Oc2ccc3ccc(OC4(CC)COC4)cc3c2)COC1 ; c1c(OC2CO2)cc(OC2CO2)cc1OC1CO1 ; C1OC1OCC(COC1CO1)(COC1CO1)COC1CO1]

Formula (1-1) corresponds to Formula (1-A) where R¹=benzene; m=2, with each R² being ethyl; each L is —O—; and n=2. Formula (1-2) corresponds to Formula (1-B) where R¹=naphthalene; m=0; each L is —O—; each R^{a} and R^{b} are methylene; and n=2. Formula (1-3) corresponds to Formula (1-A) where R¹=benzene; m=0; each L is —O—CH₂—; and n=3. Formula (1-4) corresponds to Formula (1-A) where R¹═C(CH₂) 4; m=0; each L is —O—; and n=4.

The second type of additive (Type 2) contains at least one alkenyl group or at least one alkynyl group. In particular embodiments, such additives may have the structure of Formula (2-A) or Formula (2-B):

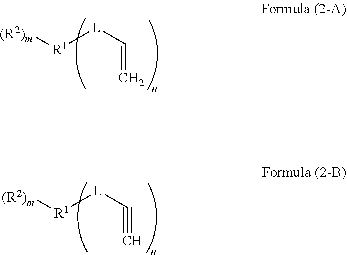

wherein R¹ is H, hydrocarbon, substituted hydrocarbon, aryl, or heteroaryl;
each R² is independently hydrocarbon or a substituent that contains a heteroatom;
m is an integer from 0 to 12;
each L is —O—, —S—, hydrocarbon, substituted hydrocarbon, or a combination thereof; and
n is an integer from 1 to 20.

When R¹ is not H, the alkenyl and alkynyl group(s) may be attached to any carbon atom or suitable heteroatom of R¹. In some particular embodiments of Formula (2-A) and Formula (2-B), R¹ is aryl or alkyl having 1 to 20 carbon atoms. In other particular embodiments, each L is —O—, —S—, alkyl, or a combination thereof. Combinations of these embodiments are also contemplated.

Again non-limiting examples of substituents for R² in Formula (2-A) and Formula (2-B) can include halogen, —OH, —SH, —NO₂, —SO₂R, —SO₃R, —CN, —COR, —CO₂R, or —CONR₂, where each R is independently hydrogen or alkyl.

Some non-limiting examples of Type 2 additives containing one or more alkenyl or alkynyl groups are shown below as Formulas (2-1) through (2-5):

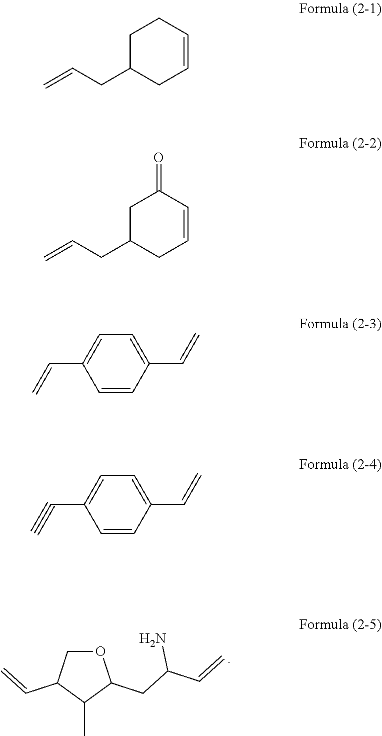

The structures of Formula (2-2) and Formula (2-5) are examples where R¹ is a substituted hydrocarbon group. In Formula (2-2), a methylene group is substituted with an oxygen atom. In Formula (2-5), a methylene group is substituted with an oxygen atom and a hydrogen atom is substituted with an amino group.

The third type of additive (Type 3) is an oxyalkyl melamine. In particular embodiments, the oxyalkyl melamino has the structure of Formula (3-A):

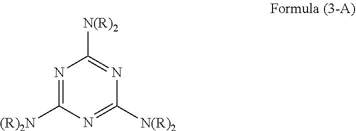

wherein each R is independently H or

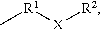

and at least one R is

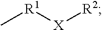

each R¹ is independently alkyl or substituted alkyl;
each X is independently O or S; and
each R² is H, alkyl, aryl, or a combination thereof.

The melamine may have 1 to 6 separate oxyalkyl chains. In particular embodiments of Formula (3-A), each R² contains 1 to 20 carbon atoms. In some particular embodiments of Formula (3-A), each R² is alkyl, fluoroalkyl, or aryl having 1 to 20 carbon atoms. In more specific embodiments of Formula (3-A), each R² is H, methyl, or benzyl (a combination of alkyl and aryl). In even more specific embodiments of Formula (3-A), R is hydroxymethyl.

Some non-limiting examples of Type 3 melamine additives are shown below as Formulas (3-1) through (3-6):

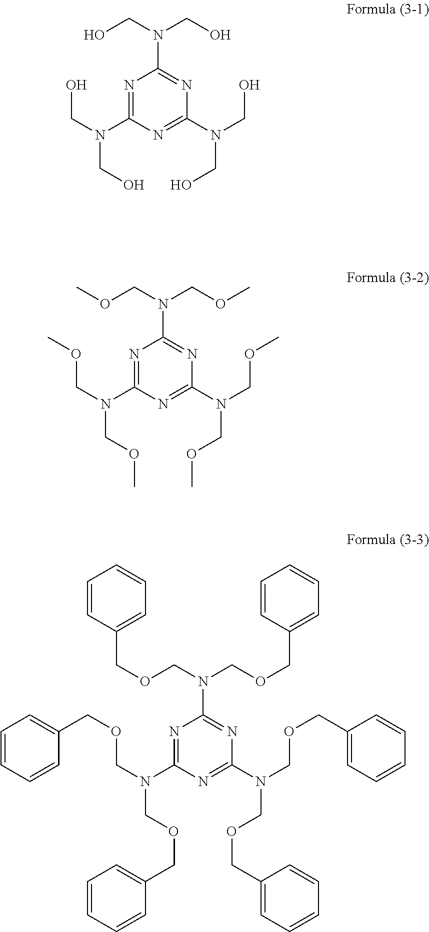

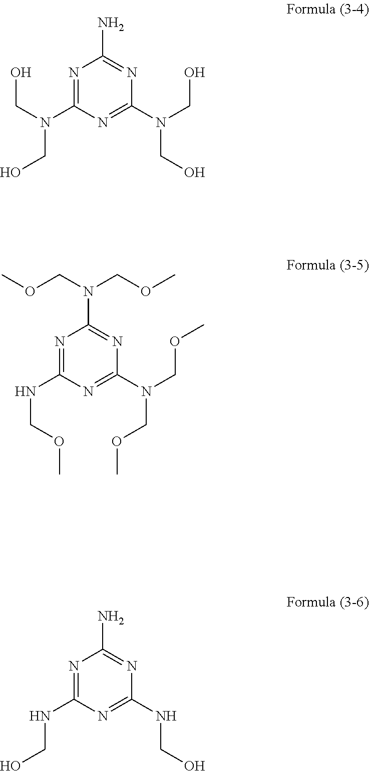

The fourth type of additive (Type 4) contains at least one phosphonic acid group or at least one silane group. In particular embodiments, such additives may have the structure of Formula (4-A) or Formula (4-B):

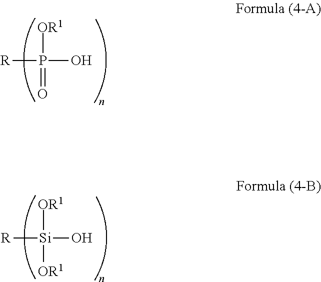

wherein R is H, hydrocarbon, substituted hydrocarbon, aryl, or heteroaryl;
each R¹ is independently hydrogen or alkyl; and
n is an integer from 1 to 20.

In some particular embodiments, each R¹ is hydrogen. In some more particular embodiments of Formula (4-A) and Formula (4-B), R is alkyl, fluoroalkyl, or aryl having 1 to 20 carbon atoms. Combinations of these embodiments are also contemplated. Some non-limiting examples of Type 4 additives containing a phosphonic acid group or a silane group are shown below as Formulas (4-1) and (4-2):

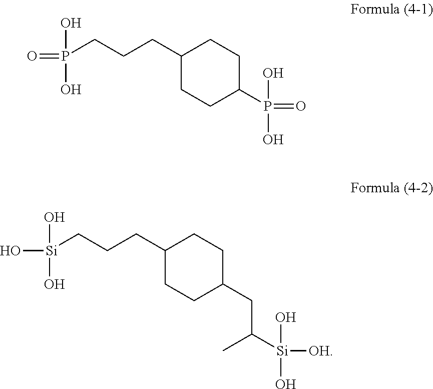 [SMILES: O=P(O)(O)CCCC1CCC(P(=O)(O)O)CC1 ; CC(CC1CCC(CCC[Si](O)(O)O)CC1)[Si](O)(O)O]

The fifth type of additive (Type 5) is an aromatic alcohol or ether derivative. In particular embodiments, such additives may have the structure of Formula (5-A):

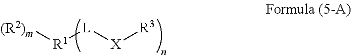

wherein R¹ contains one or more aryl or heteroaryl groups which may be linked together via a covalent bond or an alkyl group;
each R² is independently alkyl, fluoroalkyl, aryl, or a substituent that contains a heteroatom;
m is an integer from 0 to 12;
each L is hydrocarbon, substituted hydrocarbon, or a combination thereof;
each X is O or S;
each R³ is hydrocarbon, substituted hydrocarbon, aryl, or heteroaryl; and
n is an integer from 1 to 20.

In some particular embodiments of Formula (5-A), each R³ is alkyl, fluoroalkyl, or aryl having 1 to 20 carbon atoms. In other particular embodiments, R¹ is aryl, such as benzene, naphthalene, anthracene, or phenanthrene. Combinations of these embodiments are also contemplated. The substituents (indicated by m and n) may be attached to any carbon atom or suitable heteroatom of R¹.

Some non-limiting examples of Type 5 additives containing an aromatic alcohol or ether group are shown below as Formulas (5-1) through (5-6):

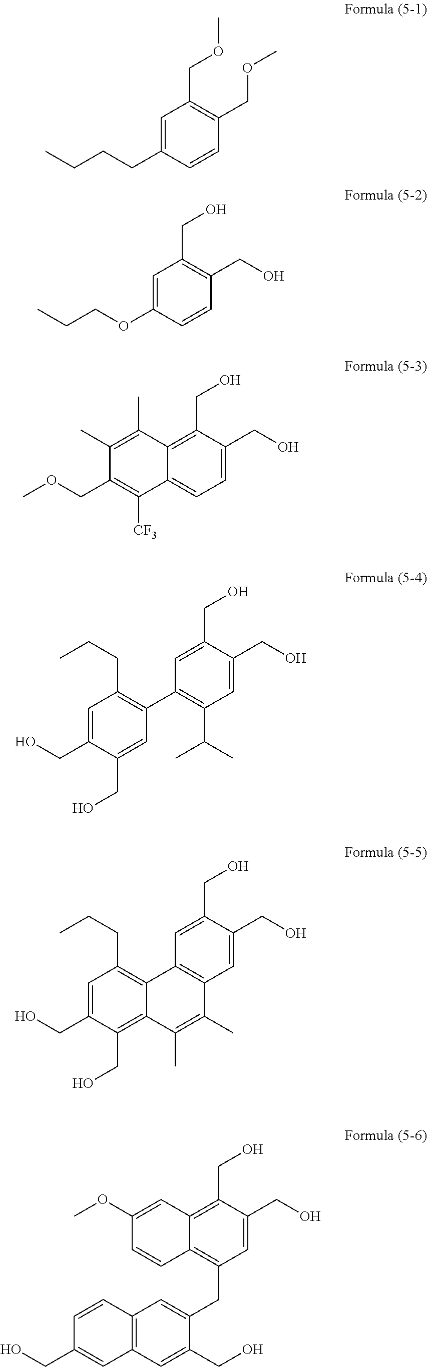

Formula (5-1) corresponds to Formula (5-A) where R¹=benzene; each L is —CH₂—; each X is O, each R³═H; n=2; R²=n-butyl; and m=1. Formula (5-2) corresponds to Formula (5-A) where R²=n-propoxy; and m=1. In Formula (5-3), n=3, containing two alcohol groups and one ether group; and m=3, with R² being two methyl groups and one trifluoromethyl groups. In Formula (5-4), R¹=biphenyl (a combination of two aryl groups linked together via a covalent bond); n=4, with four alcohol groups; and m=2, with R² being one n-propyl group and one isopropyl group. In Formula (5-5), R¹=phenanthrene; n=3, with three alcohol groups; and m=3, with R² being one n-propyl group and two methyl groups. In Formula (5-6), R¹=two naphthalene groups linked together via a methylene group; and n=5, with five alcohol groups

The sixth type of additive (Type 6) contains at least one acrylate group. In particular embodiments, such additives have the structure of Formula (6-A):

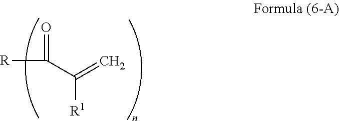

wherein R is H, hydrocarbon, substituted hydrocarbon, aryl, or heteroaryl, or a combination thereof which may be linked together via a covalent bond or an alkyl group;
each R¹ is independently hydrogen or alkyl; and
n is an integer from 1 to 20.

In some particular embodiments of Formula (6-A), R is alkyl, fluoroalkyl, or aryl having 1 to 20 carbon atoms. In other particular embodiments, R¹ is methyl, so as to be a methacrylate group. Each acrylate group may be attached to any carbon atom or suitable heteroatom of R¹. Combinations of these embodiments are also contemplated.

Some non-limiting examples of Type 6 additives containing one or more acrylate groups are shown below as Formulas (6-1) through (6-3):

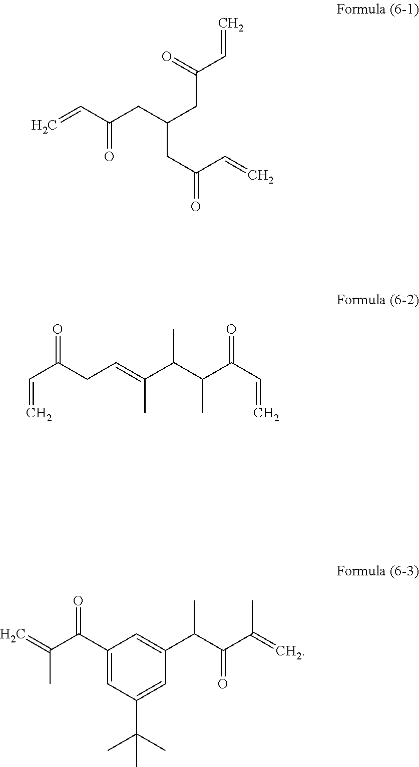

The seventh type of additive (Type 7) contains at least one thiol group. In particular embodiments, such additives have the structure of Formula (7-A):

R—(SH)ₙ (Formula 7-A)
wherein R is hydrocarbon, substituted hydrocarbon, aryl, or heteroaryl, or a combination thereof which may be linked together via a covalent bond or an alkyl group; and
n is an integer from 1 to 20.
hydrocarbon, substituted hydrocarbon, aryl, or heteroaryl; and
n is an integer from 1 to 20.

In some particular embodiments of Formula (7-A), R is alkyl, fluoroalkyl, or aryl having 1 to 20 carbon atoms. Each thiol group may be attached to any carbon atom or suitable heteroatom of R. One non-limiting example of a Type 7 additive containing one or more thiol groups is shown below as Formula (7-1), where R is methylbenzene and n=2:

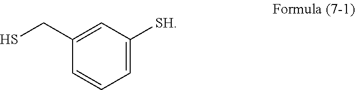

The eighth type of additive (Type 8) contains at least one amino group. In particular embodiments, such additives may have the structure of Formula (8-A):

R—(NHR¹)ₙ Formula (8-A)
wherein R is hydrocarbon, substituted hydrocarbon, aryl, or heteroaryl, or a combination thereof which may be linked together via a covalent bond or an alkyl group; and n is an integer from 1 to 20.

In some particular embodiments of Formula (8-A), R is alkyl, fluoroalkyl, or aryl having 1 to 20 carbon atoms. In other embodiments, at least one R¹ group is not hydrogen. Each amino group may be attached to any carbon atom or suitable heteroatom of R. Combinations of these embodiments are also contemplated. One non-limiting example of a Type 8 additive containing one or more amino groups is shown below as Formula (8-1), which contains one —NH₂ group and one amino group where R¹ is ethyl:

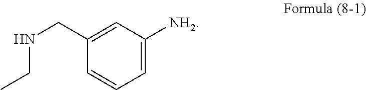

The ninth type of additive (Type 9) contains at least one isocyanate group. In particular embodiments, such additives may have the structure of Formula (9-A):

R—(NCO)ₙ Formula (9-A)
wherein R is H, hydrocarbon, substituted hydrocarbon, aryl, or heteroaryl, or a combination thereof which may be linked together via a covalent bond or an alkyl group; and
n is an integer from 1 to 20.

In some particular embodiments of Formula (9-A), R is alkyl, fluoroalkyl, or aryl having 1 to 20 carbon atoms. Each isocyanate group may be attached to any carbon atom or suitable heteroatom of R. One non-limiting example of a Type 9 additive containing one or more isocyanate groups is shown below as Formula (9-1), which contains two isocyanate groups and where R is a combination of two aryl groups linked together via an alkyl group:

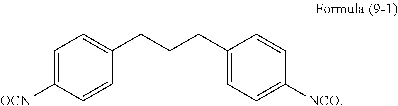

The tenth type of additive (Type 10) contains at least one acylurea group. In particular embodiments, such additives may have the structure of Formula (10-A):

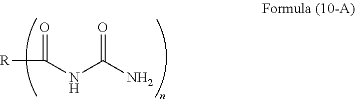

wherein R is H, hydrocarbon, substituted hydrocarbon, aryl, or heteroaryl, or a combination thereof which may be linked together via a covalent bond or an alkyl group; and
n is an integer from 1 to 20.

In some particular embodiments of Formula (10-A), R is alkyl, fluoroalkyl, or aryl having 1 to 20 carbon atoms. Each acylurea group may be attached to any carbon atom or suitable heteroatom of R.

The eleventh type of additive (Type 11) contains at least one anhydride group. In particular embodiments, such additives may have the structure of Formula (11-A) or Formula (11-B):

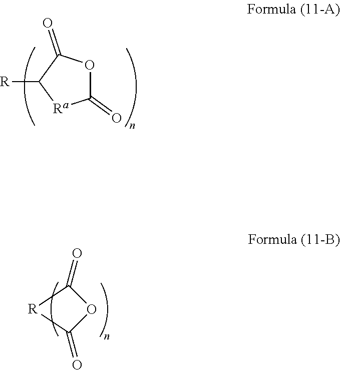

wherein R is H, hydrocarbon, substituted hydrocarbon, aryl, or heteroaryl, or a combination thereof which may be linked together via a covalent bond or an alkyl group;
each R^{a} is independently alkylene having at least 1 carbon atom; and
n is an integer from 1 to 20.

In particular embodiments of Formula (11-A), R^{a} is alkylene having 1 to 20 carbon atoms. As can be seen in Formula (11-B), the anhydride group may be attached to the R group through one or more carbon atoms. In some particular embodiments of Formula (11-A) and Formula (11-B), R is alkyl, fluoroalkyl, or aryl having 1 to 20 carbon atoms. Combinations of these embodiments are also contemplated. Each anhydride group may be attached to any carbon atom(s) or suitable heteroatom(s) of R. The structures of Formula (11-A) and Formula (11-B) should also be construed as including compounds having two carboxylic acid groups.

One non-limiting example of a Type 11 additive containing an anhydride group is shown below as Formula (11-1), which corresponds to Formula (11-B) where R is cyclohexane and n=2:

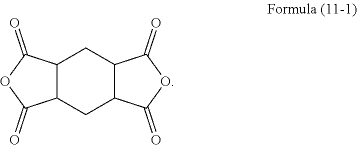 [SMILES: O=C1OC(=O)C2CC3C(=O)OC(=O)C3CC12]

The twelfth type of additive (Type 12) contains at least one acyl halide group. In particular embodiments, such additives may have the structure of Formula (12-A):

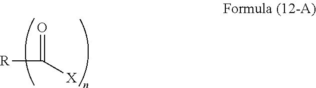

wherein R is H, hydrocarbon, substituted hydrocarbon, aryl, or heteroaryl, or a combination thereof which may be linked together via a covalent bond or an alkyl group;
each X is independently halogen; and
n is an integer from 1 to 20.

In some particular embodiments of Formula (12-A), R is alkyl, fluoroalkyl, or aryl having 1 to 20 carbon atoms. In other particular embodiments, X is chlorine. Combinations of these embodiments are also contemplated. Each acyl halide group may be attached to any carbon atom or suitable heteroatom of R. One non-limiting example of a Type 12 additive containing one or more acyl halide groups is shown below as Formula (12-1), where R is cyclohexane and n=3:

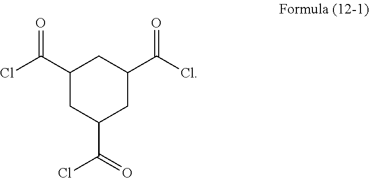 [SMILES: O=C(Cl)C1CC(C(=O)Cl)CC(C(=O)Cl)C1]

The thirteenth type of additive (Type 13) contains at least one acyl ester group. In particular embodiments, such additives may have the structure of Formula (13-A):

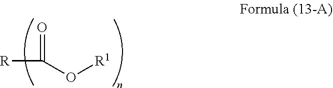

wherein R is H, hydrocarbon, substituted hydrocarbon, aryl, or heteroaryl, or a combination thereof which may be linked together via a covalent bond or an alkyl group; each R¹ is independently hydrocarbon, substituted hydrocarbon, aryl, or heteroaryl; and n is an integer from 1 to 20.

In some particular embodiments of Formula (13-A), R is alkyl, fluoroalkyl, or aryl having 1 to 20 carbon atoms. In other particular embodiments of Formula (13-A), each R¹ is alkyl, fluoroalkyl, or aryl having 1 to 20 carbon atoms. Combinations of these embodiments are also contemplated. One non-limiting example of a Type 13 additive containing one or more acyl ester groups is shown below as Formula (13-1), where R is benzene, n=2, and R¹ is ethyl:

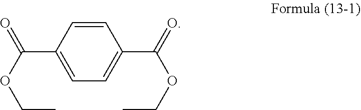 [SMILES: CCOC(=O)c1ccc(C(=O)OCC)cc1]

The additives themselves can be synthesized using conventional methods known in the art.

In particular embodiments, the additive can be used in an amount of about 0.1 wt % to about 20 wt % relative to the metallic photoresist. As will be described in further detail herein, the photoresist development process includes the steps of coating the substrate, a prebake or softbake, radiation exposure, an optional post-exposure bake, development, and an optional hardbake. The additive can be used during any of these process steps, or could be used between any of the process steps. The additive may be provided in a liquid phase or a gas/vapor phase or as a solid, depending on the operating temperature and pressure of the particular process step.

### Photoresist Solution or Treatment Solution

A photoresist solution is generally used to prepare a photoresist layer on a semiconducting wafer substrate. The photoresist solution includes a metallic photoresist as described above. The photoresist solution may also include a cross-linker as is known in the art. The photoresist solution also includes a solvent in which the photoresist and cross-linker are carried. The solvent may be, for example, water, propylene glycol methyl ether acetate (PGMEA), propylene glycol monomethyl ether (PGME), 1-ethoxy-2-propanol (PGEE), gamma-butyrolactone (GBL), cyclohexanone (CHN), ethyl lactate (EL), methanol, ethanol, propanol, n-butanol, acetone, dimethylformamide (DMF), isopropyl alcohol (IPA), tetrahydrofuran (THF), methyl isobutyl carbinol (MIBC), n-butyl acetate (nBA), 2-heptanone (MAK), or isobutyl propionate, or other suitable solvent.

The metallic photoresist may comprise from about 0.1 wt % to about 50 wt % of the photoresist solution. The cross-linker may comprise from about 0.1 wt % to about 20 wt % of the photoresist solution. The remainder of the photoresist solution is the solvent.

In some embodiments, the metallic elements in the metal core of the metallic photoresist may comprise from about 0.01 wt % to about 7 wt % of the photoresist solution. Any cross-linker is generally used in an amount of about 0.1 wt % to about 30 wt % relative to the metallic photoresist.

The photoresist solution may also include a photoacid generator (PAG). Upon exposure to radiation, the photoacid generator decomposes to generate an acid. The photoresist solution may also include a thermal acid generator (TAG). At high temperatures, the thermal acid generator decomposes to generate an acid. The acids catalyze chemical reactions which change the solubility of the photoresist, for example by cleaving the ligands from the metal core. The additive will also be triggered by the acid. Photobase generators (PBG) and thermal base generators (TBG) may also be used, which can also trigger the additive. Quenchers may also be present to enhance pattern solution by neutralizing acid which may diffuse into non-exposed areas of the photoresist.

When the additives of the present disclosure are not included in the photoresist solution, it is typically provided in a liquid form as a treatment solution. The solvent of the treatment solution may be any of the same solvents as used in the photoresist solution. The additive(s) may be dissolved to saturation in the solvent to form the treatment solution. In some embodiments, the additive may be dissolved to a final concentration of about 0.0001 wt % to about 99 wt %. Other values and ranges are also within the scope of this disclosure.

### Process

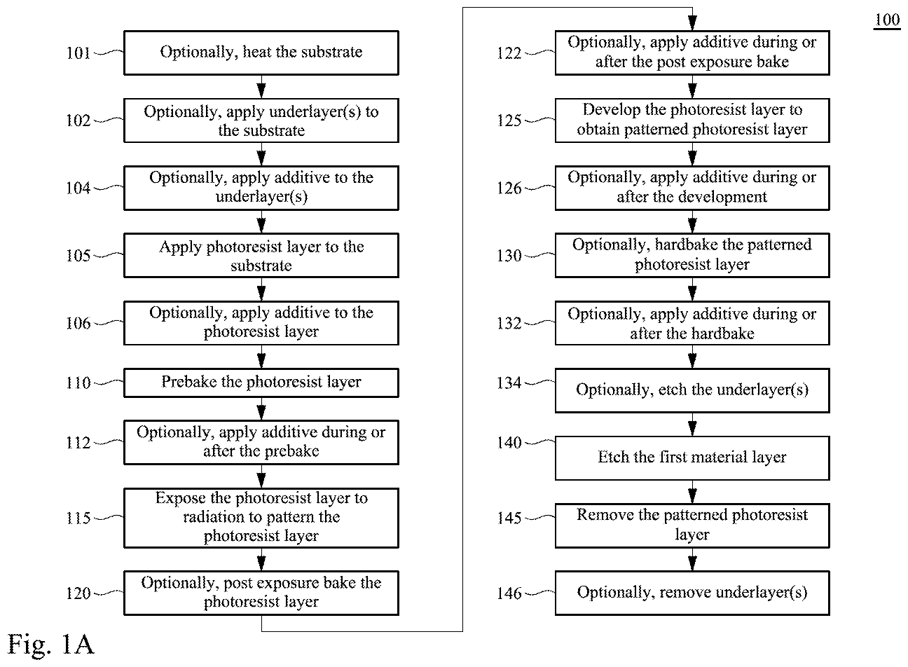

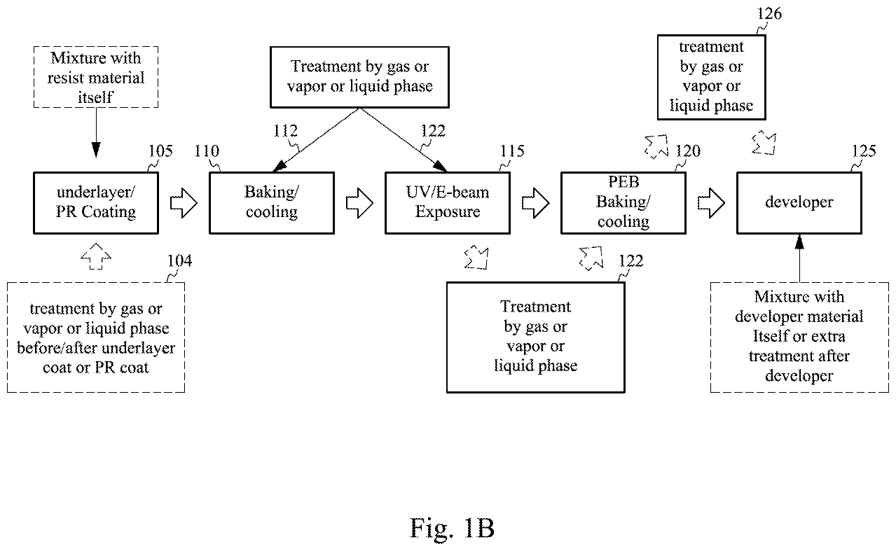

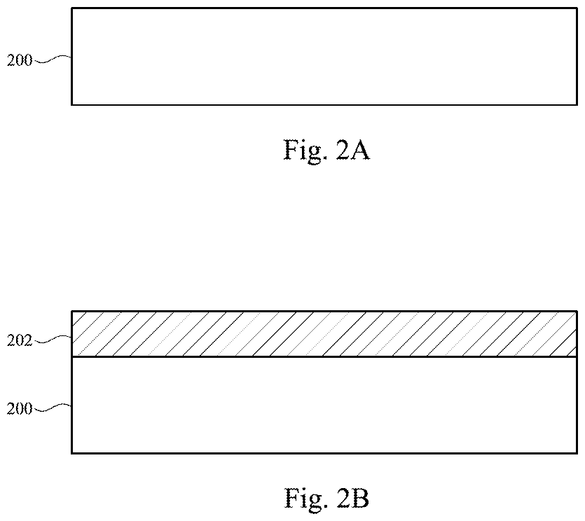

FIG. 1A is a flow chart illustrating a method 100 for preparing a patterned photoresist layer and etching a layer of a semiconducting device, in accordance with some embodiments. FIG. 1B is another flow chart illustrating other aspects of the method. In the discussion below, FIG. 1A will generally be referred to. Some steps of the method are also illustrated in FIGS. 2A-7. These figures provide different views for better understanding.

Referring first to FIG. 2A, this figure shows one example of the beginning state of the substrate 200 prior to any processing steps. The substrate is usually a wafer made of a semiconducting material. Such materials can include silicon, for example in the form of crystalline Si or polycrystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon. As illustrated here, no additional layers are present upon the substrate 200.

In contrast, in FIG. 2A, a first material layer 202 is present upon the substrate 200. The first material layer may be any material that may be used in a semiconducting device or integrated circuit. For example, the first material layer could be made of an insulating material, such as silicon dioxide (SiO₂) or silicon nitride (SiN), silicon oxynitride (SiON), fluoride-doped silicate glass, or other dielectric material. As another example, the first material layer could be made of an electrically conductive material, such as polysilicon or a metal like aluminum, copper, titanium, or tungsten. The discussion below proceeds with a first material layer being present, for illustrative purposes only and with it being understood that the substrate can also be etched.

It may be desirable to heat the substrate prior to beginning the photoresist patterning process. This optional heating step 101 may improve resist adhesion by desorbing water present on the substrate surface and to thermally crack any hydroxide bonds present on an oxidized surface. The substrate can be heated to temperatures above 100° C. up to, for example, 200° C. for a period of several minutes. The substrate is then cooled back down to room temperature.

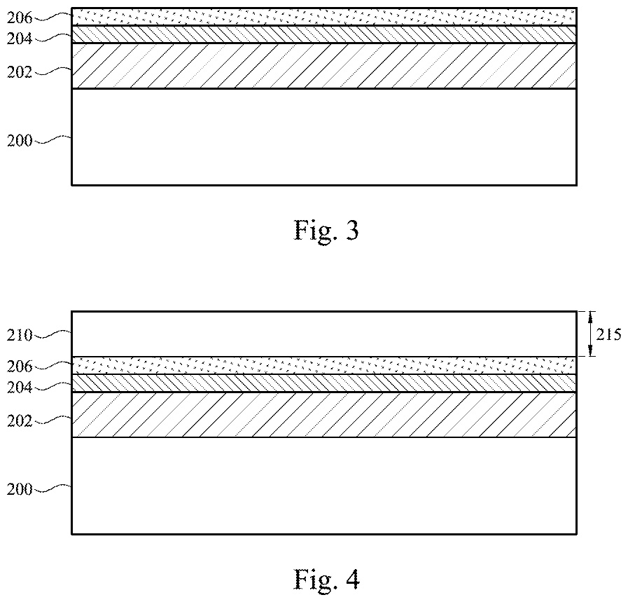

Referring again to FIG. 1A, in optional step 102, one or more underlayers are applied to the substrate. In this regard, the term “underlayer” is relative to the photoresist layer, and refers to any layers which may be applied to the layer that is desired to be etched prior to applying the photoresist layer. Put another way, any layers between the layer to be etched and the photoresist layer can be considered an underlayer. In one non-limiting example illustrated in FIG. 3, two underlayers 204, 206 are applied upon the first material layer 202.

As one example, the lower underlayer 204 may be a bottom anti-reflective coating (BARC). When a photoresist layer is applied to a reflective substrate, light reflection from the substrate/resist interface can create variations in light exposure, that cause problems with critical dimension (CD) control. For example, light can reflect into areas where exposure was not intended, changing the desired pattern. A BARC can be applied between the substrate and the photoresist layer to minimize or eliminate such problems. Examples of suitable BARCs include amorphous carbon and various organic polymers. The BARC layer is typically formed by spin coating, though other methods can also be used. The BARC coating or film is then baked or cured to induce crosslinking and solvent removal, and hardening of the BARC. In some particular embodiments, the baking occurs at a temperature of about 125° C. to about 275° C. In particular embodiments, the baking takes place for a time of about 30 seconds to about 250 seconds. The baking can be performed using a hot plate or similar equipment.

As another example, the upper underlayer 206 may be a hard mask layer. The hard mask layer may be formed from a dielectric material, a metal, or other suitable material. Examples of suitable dielectric materials may include silicon carbide, silicon nitride, silicon oxycarbide, or silicon oxynitride. The hard mask layer may be formed by any suitable process such as chemical vapor deposition (CVD), low-pressure CVD (LPCVD), plasma-enhanced CVD (PECVD), physical vapor deposition (PVD), atomic layer deposition (ALD), or spin coating. The BARC layer and the hard mask layer are also typically selected to have significantly different etching sensitivity towards the same etchant. Combined with the photoresist layer, this multi-layer resist pattern can also help improve line width roughness (LWR).

When underlayers are used, as indicated in optional step 104 of FIG. 1A, the additive can be mixed in with the materials for the underlayer or applied to either underlayer. This can be done by applying the additive in the liquid phase (e.g. a solution) or in the gas phase, for example during the baking/curing of the underlayer. Alternatively, the additive could be applied as a solid.

Next, in step 105 of FIG. 1A and as illustrated in FIG. 4, a photoresist (PR) layer 210 is applied over the substrate. The photoresist layer is formed by applying the photoresist solution containing the metallic photoresist and/or the additive. The photoresist solution may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist solution is then applied to the center of the substrate. The speed of the rotating platen is then increased to spread the resist evenly from the center of the substrate to the perimeter of the substrate. The rotating speed of the platen is then fixed, which can control the thickness of the final photoresist layer. FIG. 4 shows the resulting structure after this step.

Alternatively, as indicated in optional step 106 of FIG. 1A, the additive can be applied after the photoresist layer has been applied. Again, the additive could be applied in the liquid phase, for example by spin coating or spraying or misting the treatment solution upon the photoresist layer. Alternatively, the additive could be applied as a solid or a gas.

Next, in step 110 of FIG. 1A, the photoresist solution is prebaked to remove the solvent and harden the photoresist layer. This may also be referred to as a softbake. In some particular embodiments, the prebake occurs at a temperature of about 40° C. to about 100° C., including from about 250° C. to about 800° C. or from about 90° C. to about 110° C. The time for the prebake may depend upon the thickness of the photoresist layer 210, with longer times for greater thicknesses, and in particular embodiments from about 10 seconds to about 10 minutes. Referring to FIG. 4, the photoresist layer 210 may have a thickness 215 of about 10 nanometers to about 100 nanometers. The baking can be performed using a hot plate or oven, or similar equipment. As a result, the photoresist layer is formed on the substrate. The substrate and the other layers thereon are then cooled down to room temperature.

As indicated in optional step 112 of FIG. 1A, the additive can be applied during or after the prebake. The additive could be applied as a liquid, or can be vaporized by the heating that occurs in the prebake step and be applied as a gas. Alternatively, the additive could be applied as a solid.

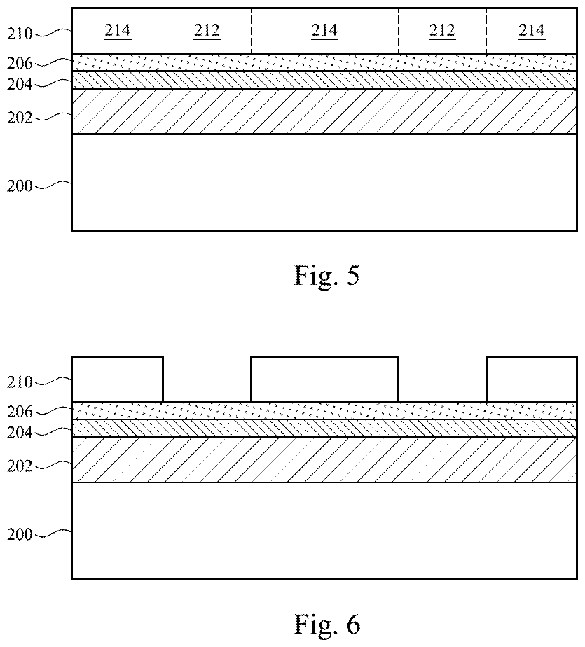

Continuing, in step 115 of FIG. 1A, the photoresist layer 210 is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. In other embodiments, electron-beam (e-beam) radiation is used. Electron beams can be characterized by the energy of the beam, which in some embodiments ranges from about 5 volts (V) to about 200 kilovolts (kV). This step results in some portions of the photoresist layer being exposed to radiation, and some portions of the photoresist not being exposed to radiation. This exposure causes some portions of the photoresist to remain soluble in the developer and other portions of the photoresist to become insoluble in the developer. Referring now to FIG. 5, the photoresist layer 210 now includes soluble regions 212 and insoluble regions 214. It is noted for reference that EUV and e-beam radiation exposure typically occur under vacuum.

Prior to radiation exposure or heat exposure, the additive does not react with the metallic photoresist. When exposed to radiation or heat, the additive reacts either with the metallic photoresist or with itself (including other additives, if more than one of the 13 types described above is used).

Optionally, in step 120 of FIG. 1A, a post exposure bake (PEB) occurs after the exposure to radiation. The PEB step can be used to complete any cross-linking within the photoresist. In addition, the PEB step may reduce mechanical stress that might build up during the prior steps. In some particular embodiments, the PEB occurs at a temperature of about 40° C. to about 250° C., including from about 100° C. to about 250° C. or from about 90° C. to about 150° C. The time for the PEB may range from about 10 seconds to about 10 minutes, and may vary depending on the thickness of the photoresist layer.

As indicated in optional step 122 of FIG. 1A, the additive can be applied during or after the post exposure bake. The additive could be applied as a liquid or vaporized to enter the gas phase during the heating that occurs in the PEB step, or applied as a solid.

Next, in step 125 of FIG. 1A, the photoresist layer 210 is developed using a developer. The developer may be applied by spin coating, spraying, or other suitable process. The soluble portions of the photoresist layer are dissolved and washed away during the development step, leaving behind a patterned photoresist layer. This may be done, for example, by spin drying. Suitable developers may include PGMEA, PGME, PGEE, GBL, cyclohexanone, ethyl lactate, methanol, ethanol, propanol, n-butanol, acetone, DMF, isopropyl alcohol (IPA), THF, MIBC, n-butyl acetate, MAK, or isobutyl propionate, i.e. the same solvent used in the photoresist solution. Other developers could include aqueous tetramethylammonium hydroxide (TMAH), isoamyl acetate, cyclohexanone, 5-methyl-2-hexanone, methyl-2-hydroxyisobutyrate, n-pentyl acetate, n-butyl propionate, n-hexyl acetate, n-butyl butyrate, isobutyl butyrate, 2,5-dimethyl-4-hexanone, 2,6-dimethyl-4-heptanone, propyl isobutyrate, or isobutyl propionate. Generally, any suitable developer may be used.

If desired, the additive can be mixed directly into the developer. Alternatively, as indicated in optional step 126 of FIG. 1A, the additive can be applied after the developer has been applied and then washed off the substrate. Again, the additive could be applied in the liquid phase, for example by spin coating or spraying or misting the treatment solution, or could be applied as a solid or a gas. The resulting structure is illustrated in FIG. 6. As seen here, the soluble regions have been washed away, resulting in a patterned photoresist layer.

In optional step 130 of FIG. 1A, a post develop bake or “hardbake” may be performed after development. This can be done to stabilize the photoresist pattern after development, for optimum performance in subsequent steps. In some particular embodiments, the hardbake occurs at a temperature of about 100° C. to about 160° C. The time for the hardbake may range from about 1 minute to about 10 minutes, and may vary depending on the thickness of the photoresist layer.

As indicated in optional step 132 of FIG. 1A, the additive can be applied during or after the hardbake. The additive could be applied as a liquid (i.e. treatment solution) or vaporized to enter the gas phase during the heating that occurs in the hardbake step, or applied as a solid.

The various baking steps may be useful in enhancing the reaction of the additive with itself or with the metallic photoresist. In some embodiments, a baking step may occur at any temperature ranging from about 40° C. to about 300° C.

Continuing, then, portions of the upper underlayer 206, the lower underlayer 204, and the first material layer 202 are exposed below the first patterned photoresist layer are now exposed.

In optional step 134 of FIG. 1A, the underlayer(s) 206, 204 are etched, thus transferring the photoresist pattern to the underlayers. Then, in step 140 of FIG. 1A, the first material layer 202 is etched, thus transferring the photoresist pattern to the first material layer. Desirably, each of the etchants for these layers differs significantly from that of the other layers, which improves the LWR in the first material layer.

Generally, these etching steps may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), trifluoromethane (CHF₃), carbon fluorides, nitrogen (N₂), hydrogen (H₂), oxygen (O₂), argon (Ar), xenon (Xe), xenon difluoride (XeF₂), helium (He), carbon monoxide (CO), carbon dioxide (CO₂), fluorine (F₂), chlorine (Cl₂), oxygen (O₂), hydrogen bromide (HBr), hydrofluoric acid (HF), nitrogen trifluoride (NF₃), sulfur hexafluoride (SF₆), boron trichloride (BCl₃), ammonia (NH₃), bromine (Br₂), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or H₂.

Referring now to FIG. 1B, the two different treatment options are shown more clearly here. In the photoresist coating step 105 and the developing step 125, the additive can be directly mixed into the photoresist solution or the development solution. This is indicated in dotted lines. Alternatively, the additive can be used in the form of a treatment solution which is applied to the photoresist. More desirably, the additive is used before, during, or after a step in which energy is added to the photoresist. Those include the radiation exposure step 115, the pre-bake step 110, and the post exposure bake step 120, in which light energy or thermal energy are added. This is indicated with solid lines.

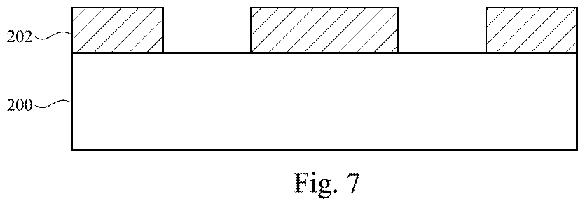

Next, in step 145 of FIG. 1A, the patterned photoresist layer 210 is removed. In optional step 146, the upper underlayer 206 is removed. In optional step 148, the lower underlayer 204 is removed. The photoresist layer, the upper underlayer, and the lower underlayer can be removed using conventional means such as plasma stripping, solvent, or chemical-mechanical planarization (CMP). The resulting structure is illustrated in FIG. 7, with the first material layer 202 being patterned.

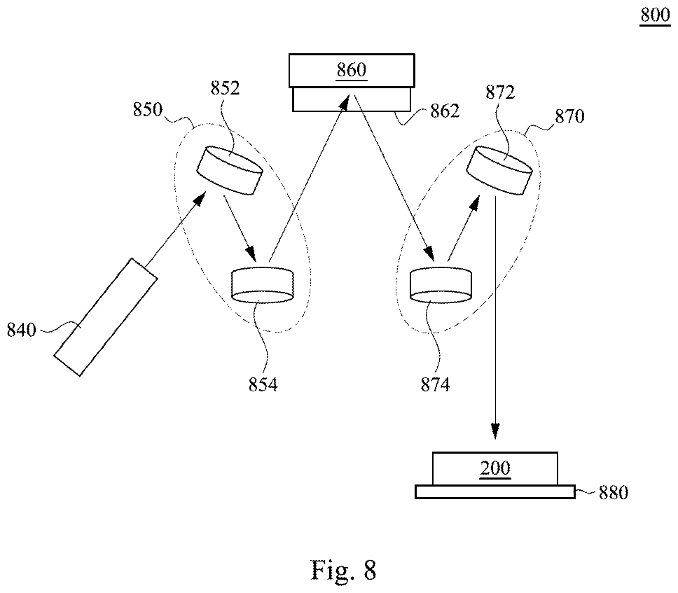

FIG. 8 is an illustrative schematic diagram, not drawn to scale, illustrating the various components of an extreme ultraviolet (EUV) photolithography system which generates the radiation to which the photoresist is exposed. Generally, the EUV photolithography system 800 begins with an EUV light source 840 that generates EUV light or radiation. Downstream of the EUV light source is an illumination stage 850 in which the EUV light may be collected and focused as a beam, for example using field facet mirror 852 that splits the beam into a plurality of light channels. These light channels can then directed using one or more relay mirrors 854 onto the plane of the photomask. The photomask 860 may include a pellicle membrane 862, through which the radiation passes before and/or after contacting the photomask. Downstream of the photomask 860 is the projection optics module 870, which is configured for imaging the pattern of the photomask onto the semiconductor wafer substrate 200. The projection optics module 870 may include refractive optics or reflective optics for carrying the image of the pattern defined by the photomask. Illustrative mirrors 872, 874 are shown. The wafer substrate 200 is positioned upon a wafer stage 880, which can move as necessary for imaging. The lithography system can include other modules or be integrated with or coupled to other modules.

Additional processing steps may be performed to fabricate a semiconductor device or integrated circuit. Examples of such steps may include ion implantation, deposition of other materials, etching, etc.

Use of the specified additives during the photoresist development process provides some advantages. The hardness of the metallic photoresist layer can be increased by 1% or more. In some particular embodiments, the resulting hardness of the metallic photoresist layer is from about 0.01 GPa to about 100 GPa, although other ranges and values are within the scope of this disclosure. The line width roughness (LWR) and critical dimension uniformity (CDU) can be improved by 3% or more. The optimum energy (Eop) for lithography can also be improved by 3% or more. The metallic photoresist may have improved thermal stability as well, which also improves pattern fidelity. Processes with a pitch of 40 nanometers or lower can be improved using these components in the photoresist.

Some embodiments of the present disclosure thus relate to methods for preparing a patterned photoresist layer. A substrate is coated with a photoresist solution that includes a photoresist and an additive. In some embodiments, the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group. In some other embodiments, the additive is an oxyalkyl melamine or is an aromatic alcohol or ether.

Other embodiments of the present disclosure relate to a photoresist solution that comprises a metallic photoresist and an additive. In some embodiments, the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group. In some other embodiments, the additive is an oxyalkyl melamine or is an aromatic alcohol or ether.

Finally, other embodiments of the present disclosure relate to methods that use a photoresist solution. The substrate is coated with a photoresist solution. The coated substrate is pre-baked to cure the photoresist solution and form a photoresist layer. The photoresist layer is then exposed to radiation to pattern the photoresist layer. An optional post-exposure bake of the coated substrate may be performed. The patterned photoresist layer is then developed using a developer. The photoresist solution or the developer may include an additive. Alternatively, the coated substrate is treated with a treatment solution that contains the additive during or after the coating, pre-baking, exposing, optional post-exposure bake, or developing steps. In some embodiments, the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group. In some other embodiments, the additive is an oxyalkyl melamine or is an aromatic alcohol or ether.

Additional embodiments of the present disclosure relate to additives which can be used to increase the hardness of a metallic photoresist. In some embodiments, the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group. In some other embodiments, the additive is an oxyalkyl melamine or is an aromatic alcohol or ether.

Further embodiments of the present disclosure relate to a metallic photoresist layer with enhanced hardness. The metallic photoresist layer is further hardened by application of an additive (as described above) and subsequent radiation exposure. Various reactions may occur that harden the metallic photoresist layer.

Also disclosed herein in some embodiments are wafer substrates with a hardened metallic photoresist layer thereon. The hardened metallic photoresist layer is produced as described above.

Also disclosed herein are photolithography systems having a wafer substrate therein with a hardened metallic photoresist layer thereon. The photolithography system includes an EUV light source, an illumination stage, a photomask, a projection optics module, and a wafer stage upon which the wafer substrate rests.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for preparing a patterned photoresist layer, comprising:
coating a substrate with a photoresist solution that includes a photoresist and an additive;
wherein the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group; or
wherein the additive is an oxyalkyl melamine or is an aromatic alcohol or ether.

2. The method of claim 1, wherein the additive has the structure of Formula (1-A) or Formula (1-B): 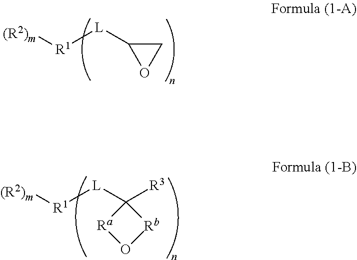
wherein R¹ is H, hydrocarbon, substituted hydrocarbon, aryl, or heteroaryl;
each R² is independently hydrocarbon or a substituent that contains a heteroatom;
m is an integer from 0 to 12;
each L is —O—, —S—, hydrocarbon, substituted hydrocarbon, or a combination thereof;
each R^{a} and R^{b} are independently alkylene having 0 to 3 carbon atoms but together have a minimum of 2 carbon atoms;
each R³ is independently H, hydrocarbon, substituted hydrocarbon, aryl, or heteroaryl; and
n is an integer from 1 to 20.

3. The method of claim 1, wherein the additive has the structure of Formula (2-A) or Formula (2-B): 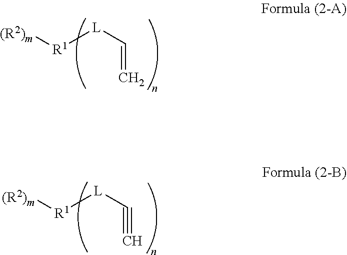
wherein R¹ is H, hydrocarbon, substituted hydrocarbon, aryl, or heteroaryl;
each R² is independently hydrocarbon or a substituent that contains a heteroatom;
m is an integer from 0 to 12;
each L is —O—, —S—, hydrocarbon, substituted hydrocarbon, or a combination thereof; and
n is an integer from 1 to 20.

4. The method of claim 1, wherein the additive has the structure of Formula (3-A): 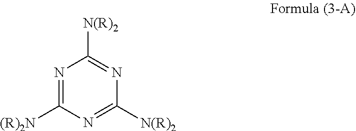
wherein each R is independently H or 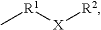
and at least one R is 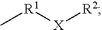
each R¹ is independently alkyl or substituted alkyl;
each X is independently O or S; and
each R² is H, alkyl, aryl, or a combination thereof.

5. The method of claim 1, wherein the additive has the structure of Formula (4-A) or Formula (4-B): 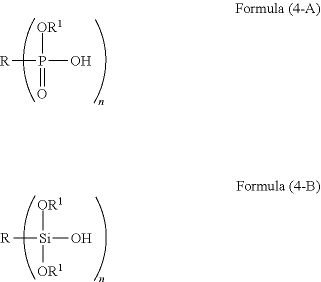
wherein R is H, hydrocarbon, substituted hydrocarbon, aryl, or heteroaryl;
each R¹ is independently hydrogen or alkyl; and
n is an integer from 1 to 20.

6. The method of claim 1, wherein the additive has the structure of Formula (5-A): 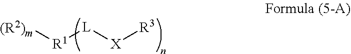
wherein R¹ contains one or more aryl or heteroaryl groups which may be linked together via a covalent bond or an alkyl group;
each R² is independently alkyl, fluoroalkyl, aryl, or a substituent that contains a heteroatom;
m is an integer from 0 to 12;
each L is hydrocarbon, substituted hydrocarbon, or a combination thereof;
each X is O or S;
each R³ is hydrocarbon, substituted hydrocarbon, aryl, or heteroaryl; and
n is an integer from 1 to 20.

7. The method of claim 1, wherein the additive has the structure of Formula (6-A): 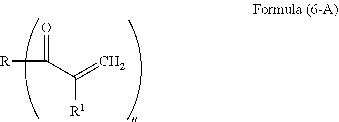
wherein R is H, hydrocarbon, substituted hydrocarbon, aryl, or heteroaryl, or a combination thereof which may be linked together via a covalent bond or an alkyl group;
each R¹ is independently hydrogen or alkyl; and
n is an integer from 1 to 20.

8. The method of claim 1, wherein the additive has the structure of Formula (7-A):
R—(SH)ₙ (Formula 7-A)
wherein R is hydrocarbon, substituted hydrocarbon, aryl, or heteroaryl, or a combination thereof which may be linked together via a covalent bond or an alkyl group; and
n is an integer from 1 to 20.
hydrocarbon, substituted hydrocarbon, aryl, or heteroaryl; and
n is an integer from 1 to 20.

9. The method of claim 1, wherein the additive has the structure of Formula (8-A):
R—(NHR¹)ₙ Formula (8-A)
wherein R is hydrocarbon, substituted hydrocarbon, aryl, or heteroaryl, or a combination thereof which may be linked together via a covalent bond or an alkyl group; and
n is an integer from 1 to 20.

10. The method of claim 1, wherein the additive has the structure of Formula (9-A):
R—(NCO)ₙ Formula (9-A)
wherein R is H, hydrocarbon, substituted hydrocarbon, aryl, or heteroaryl, or a combination thereof which may be linked together via a covalent bond or an alkyl group; and
n is an integer from 1 to 20.

11. The method of claim 1, wherein the additive has the structure of Formula 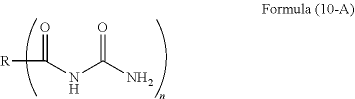
wherein R is H, hydrocarbon, substituted hydrocarbon, aryl, or heteroaryl, or a combination thereof which may be linked together via a covalent bond or an alkyl group; and
n is an integer from 1 to 20.

12. The method of claim 1, wherein the additive has the structure of Formula (11-A) or Formula (11-B): 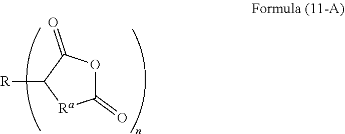 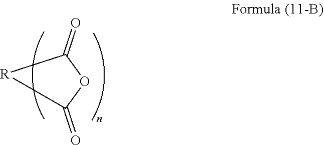
wherein R is H, hydrocarbon, substituted hydrocarbon, aryl, or heteroaryl, or a combination thereof which may be linked together via a covalent bond or an alkyl group;
each R^{a} is independently alkylene having at least 1 carbon atom; and
n is an integer from 1 to 20.

13. The method of claim 1, wherein the additive has the structure of Formula 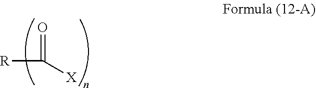
wherein R is H, hydrocarbon, substituted hydrocarbon, aryl, or heteroaryl, or a combination thereof which may be linked together via a covalent bond or an alkyl group;
each X is independently halogen; and
n is an integer from 1 to 20.

14. The method of claim 1, wherein the additive has the structure of Formula (13-A): 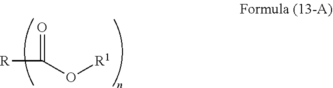
wherein R is H, hydrocarbon, substituted hydrocarbon, aryl, or heteroaryl, or a combination thereof which may be linked together via a covalent bond or an alkyl group;
each R¹ is independently hydrocarbon, substituted hydrocarbon, aryl, or heteroaryl; and
n is an integer from 1 to 20.

15. The method of claim 1, wherein the additive has a molecular weight of about 30 to about 2000.

16. The method of claim 1, further comprising:
pre-baking the applied photoresist solution to form a photoresist layer;
exposing the photoresist layer to radiation to pattern the photoresist layer; and
developing the photoresist layer to obtain a patterned photoresist layer.

17. A photoresist solution, comprising:
a metallic photoresist and an additive;
wherein the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group; or
wherein the additive is an oxyalkyl melamine or is an aromatic alcohol or ether.

18. The photoresist solution of claim 17, wherein the additive has a molecular weight of about 30 to about 2000.

19. A method, comprising:
coating a substrate with a photoresist solution;
pre-baking the coated substrate to cure the photoresist solution and form a photoresist layer;
exposing the photoresist layer to radiation to pattern the photoresist layer;
optionally performing a post-exposure bake of the coated substrate; and
developing the patterned photoresist layer using a developer;
wherein the photoresist solution or the developer includes an additive; or
wherein the coated substrate is treated with a treatment solution that contains an additive during or after the coating, pre-baking, exposing, optional post-exposure bake, or developing steps; and
wherein the additive comprises at least one cyclic ether group, or at least one alkenyl group or alkynyl group, or at least one phosphonic acid group or silane group, or at least one acrylate group, or at least one thiol group, or at least one amino group, or at least one isocyanate group, or at least one acylurea group, or at least one anhydride group, or at least one acyl halide group, or at least one acyl ester group; or
wherein the additive is an oxyalkyl melamine or is an aromatic alcohol or ether.

20. The method of claim 19, wherein the additive is triggered by an acid or a base.
